(19) United States
(12) Patent Application Publication
(10) Pub. No.: US 2025/0391810 A1
(43) Pub. Date: Dec. 25, 2025

(54) SYSTEMS FOR OPTICAL OXIDE DETECTION IN SEMICONDUCTOR DEVICES AND METHODS FOR PERFORMING THE SAME

(71) Applicant: Taiwan Semiconductor Manufacturing Company Limited, Hsinchu (TW)

(72) Inventors: Chih-Yuan Chiu, Zhudong Township (TW); Amram Eitan, Hsinchu (TW); Chi-Chun Peng, Hsinchu (TW); Yun-Han Wei, Hsinchu (TW); Wei-Ting Hsiao, Taichung City (TW)

(21) Appl. No.: 18/748,910

(22) Filed: Jun. 20, 2024

(51) Int. Cl. H01L 23/00; G01N 21/95; G06T 7/00

(52) U.S. Cl. CPC H01L 24/81; G01N 21/9501; G06T 7/001; H01L 24/16; H01L 24/75; G06T 2207/30148; H01L 2224/16227; H01L 2224/7501; H01L 2224/759; H01L 2224/81013; H01L 2224/81203; H01L 2224/81815; H01L 2224/81908

(57) ABSTRACT

Optical inspection systems and methods to detect the presence of oxide materials on bonding structures are disclosed. An optical inspection system may be integrated into a semiconductor processing tool including a plasma treatment module for removing oxide materials from bonding structures, and a bond chamber configured to bond bonding structures on a first device structure to bonding structures on a second device structure. A light source may direct light having a wavelength between 10-400 nm onto surfaces of the device structures containing the bonding structures, and a camera may obtain images of the surfaces illuminated by the light source. The images may be analyzed to detect the presence of oxide materials on the bonding structures. Accordingly, sufficient removal of oxide materials may be ensured before bonding of the device structures, which may lead to improved bond quality, increased yields, and better reliability of the bonded device structures.

### BACKGROUND

The semiconductor industry has grown due to continuous improvements in integration density of various electronic components (e.g., transistors, diodes, resistors, capacitors, etc.). For the most part, these improvements in integration density have come from successive reductions in minimum feature size, which allows more components to be integrated into a given area.

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (POP), System on Chip (SoC) or integrated SoC devices. Some of these three-dimensional devices (e.g., 3DIC, SoC, integrated SoC) are prepared by placing chips over chips on a semiconductor wafer level. These three-dimensional devices provide improved integration density and other advantages, such as faster speeds and higher bandwidth, because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of a semiconductor processing tool according to an embodiment of the present disclosure.

FIG. 2A is a vertical cross-sectional view illustrating a semiconductor integrated circuit (IC) die undergoing a plasma treatment according to various embodiments of the present disclosure.

FIG. 2C is a vertical cross-sectional view illustrating a multi-chip semiconductor IC die undergoing a plasma treatment according to various embodiments of the present disclosure.

FIG. 2B is a vertical cross-sectional view illustrating a substrate undergoing a plasma treatment according to various embodiments of the present disclosure.

FIG. 3A is a vertical cross-sectional view illustrating an optical detection system performing an inspection process on a semiconductor IC die according to various embodiments of the present disclosure.

FIG. 3B is a vertical cross-sectional view illustrating an optical detection system performing an inspection process on a substrate according to various embodiments of the present disclosure.

FIG. 3C a vertical cross-sectional view illustrating the optical detection system scanning a different region of the semiconductor IC die according to various embodiments of the present disclosure.

FIG. 4A is a grayscale image of a semiconductor IC die including an array of bonding structures obtained using a UV light source and camera according to various embodiments of the present disclosure.

FIG. 4B is a plot showing grayscale values for different pixel coordinates of an image of a semiconductor IC die that was not subjected to a plasma pre-treatment to remove oxide materials according to various embodiments of the present disclosure.

FIG. 4C is a plot showing grayscale values for different pixel coordinates of an image of a semiconductor IC die that was subjected to a plasma pre-treatment to remove oxide materials according to various embodiments of the present disclosure.

FIG. 4D is an enlarged view of a portion of a grayscale image of a second surface of a semiconductor IC die according to various embodiments of the present disclosure.

FIG. 5 is a vertical cross-section view of a bonding process used to bond a semiconductor IC die to a substrate according to various embodiments of the present disclosure,

FIG. 6 is a vertical cross-section view of a bonded device structure according to various embodiments of the present disclosure.

FIG. 7 is a flowchart illustrating a method of forming a bonded device structure according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

In advanced semiconductor packaging technologies, the demand for increased miniaturization, high-performance and high-density interconnections is growing. Fluxless thermocompression bonding is one process that has been used to create reliable and high-quality interconnections between different device structures, such as between a semiconductor integrated circuit (IC) die (i.e., “chips”) and other device structures such as a substrate, a semiconductor wafer and/or another semiconductor IC die. In a fluxless thermocompression bonding process, bonding structures, such as microbump bonding structures, on a surface of the semiconductor IC die may be aligned with and brought into contact with corresponding bonding structures on the target structure. Heat and pressure may be applied to cause bonding between mating pairs of bonding structures, and thereby bond the semiconductor IC die to the target structure. Such a bonding process may be considered fluxless as it is performed in the absence of a flux material.

In many cases, oxide material may unavoidably form over the surface of the bonding structures of the semiconductor IC die and/or the target structure. The presence of oxide materials on these bonding structures may result in poor bonding quality and may negatively affect the electrical conductivity of the bond. Thus, it may be desirable to remove oxides from the bonding structures prior to performing the bonding process, such as by performing a plasma treatment of the bonding surfaces of the semiconductor IC dies and/or the target structures before the bonding process occurs. However, there is currently no efficient real-time method or mechanism for detecting oxide materials on the bonding structures before they undergo the bonding process. Thus, even when a treatment is performed to remove oxide materials, residual oxide materials may remain that may result in poor bond formation, smaller process windows, and reduced yields. It is desirable to detect the residual oxide materials so that an effective oxide removal process may be initiated.

In order to improve the bonding between a semiconductor IC die and target structure, various embodiments of the present disclosure include optical inspection systems and methods that may be utilized to detect the presence of oxide materials on the bonding structures of the semiconductor IC die and/or the target structure prior to performing the bonding process. In various embodiments, an optical inspection system may be integrated into a semiconductor processing tool that includes a treatment module configured to treat surfaces of semiconductor IC dies and/or target structures with a plasma to remove oxide materials from the bonding structures, and a bond chamber that includes a bond head configured to bond bonding structures on the semiconductor IC dies to corresponding bonding structures on the target structure to provide a bonded device structure. The optical inspection system may include a light source configured to direct light in a wavelength range of 10 nm to 400 nm onto the surfaces of the semiconductor IC dies and/or target structures that contain the bonding structures, and a camera configured to obtain images of the surfaces of the semiconductor IC dies and/or target structures that are illuminated by the light source. The images obtained by the camera may be analyzed to detect for the presence of oxide materials on the bonding structures. In embodiments in which the optical detection system detects the presence of oxides, the semiconductor IC dies and/or target structures may undergo further plasma treatment and inspection processes until it is determined that the oxide materials have been sufficiently removed. The semiconductor IC dies and/or target structures may then be provided to the bond chamber to perform the bonding process.

Accordingly, the optical inspection system and method of the present disclosure may be utilized to ensure that oxide materials have been sufficiently removed from the bonding structures before the semiconductor IC dies and/or the target structures are provided to the bond chamber for bonding. This may lead to improved bond quality, increased yields, a larger process window and better reliability of the bonded device structures.

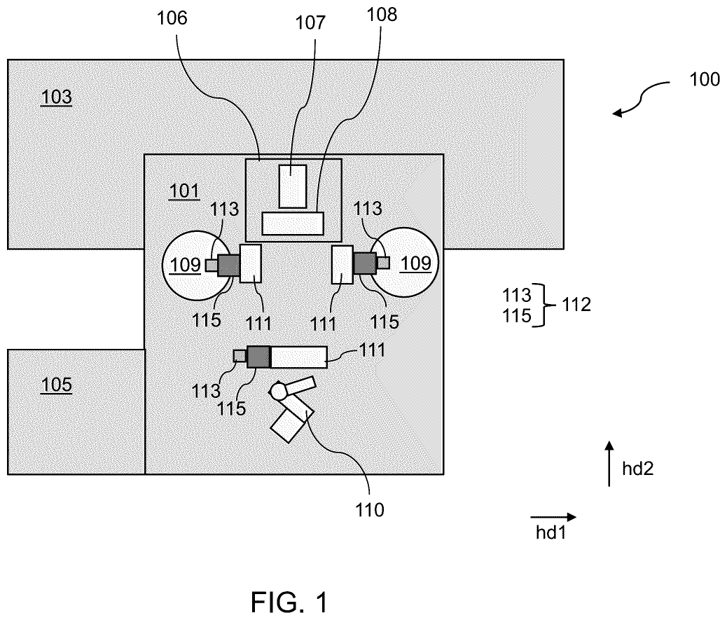

FIG. 1 is a top view of a semiconductor processing tool 100 according to various embodiments of the present disclosure. In various embodiments, the semiconductor processing tool 100 may be used for bonding semiconductor IC dies to another structure (e.g., a semiconductor wafer or substrate) to provide bonded device structures. The semiconductor processing tool 100 may include a support structure 101, at least one holder 109 (e.g., a chuck) on which substrates may be disposed, a transfer module 110 that may be used to hold semiconductor IC dies and move them to a desired location, and a bonding chamber 106 that may be used for bonding of the semiconductor IC dies to the substrates. The semiconductor processing tool 100 may be an automated, computer-controlled robotic system that may be configured to move and position the semiconductor IC dies, the substrates, and/or the bonded device structures to different locations to perform various processing and/or inspection processes.

In various embodiments, the semiconductor processing tool 100 may be integrated with an Equipment Front End Module (EFEM) 103. The EFEM 103 may function as an interface between the semiconductor processing tool 100 and the automated material handling system (AMHS) of the manufacturing facility (i.e., the “fab”). For example, the EFEM 103 may include a robotic system that is responsible for loading and unloading wafers, cassettes, and/or carriers to and from the semiconductor processing tool 100. A chip feed-in module 105 may contain semiconductor IC dies that may be provided to the transfer module 110. In various embodiments, the transfer module 110 may include a robotic arm having an end effector that may be configured to hold semiconductor IC dies using a vacuum suction force, or a similar mechanism, and to move the semiconductor IC dies to different locations on the semiconductor processing tool 100.

The bonding chamber 106 may include a bond head 107. The bond head 107 may receive semiconductor IC dies from the transfer module 110 such that the semiconductor IC dies may be secured to a lower surface of the bond head 107. In various embodiments, the bond head 107 may temporarily adhere a semiconductor IC die to the lower surface of the bond head 107 using a vacuum suction force. An actuator system may be configured to move the bond head 107 and the semiconductor IC die to align the semiconductor IC die over the surface of a target substrate and to bring the semiconductor IC die into contact with the target substrate to perform a bonding procedure as described in further detail below. In some embodiments, the bonding chamber 106 may also include an optical camera 108 that may be used to help ensure that the semiconductor IC die and the target substrate are properly aligned during the bonding procedure.

Referring again to FIG. 1, the semiconductor processing tool 100 may additionally include one or more treatment modules 111 that may be used to pre-treat the semiconductor IC dies and/or the target substrates prior to performing the bonding procedure. The pre-treatment process may include subjecting the bonding surfaces of the semiconductor IC dies and/or the target substrates with a plasma in order to remove oxide material from the bonding surfaces prior to performing the bonding process. In various embodiments, the one or more treatment modules 111 may include one or more plasma generators, such as one or more atmospheric pressure plasma jetting (APPJ) modules. The APPJ module(s) 111 may be scanned over the bonding surfaces of the semiconductor IC dies and/or the target substrates to subject the bonding surfaces to the plasma treatment, which may be achieved by moving the APPJ module(s) 111 over the bonding surfaces, moving the bonding surfaces over the APPJ module(s) 111, or moving both simultaneously.

The semiconductor processing tool 100 may also include at least one optical inspection system 112. Each optical inspection system 112 may include a light source 113 configured to direct light to the bonding surfaces of the semiconductor IC dies and/or the target substrates and a camera 115 configured to capture images of the light reflected from the bonding surfaces. As discussed in further detail below, the images obtained by the camera 115 may be analyzed to detect the presence of oxide material on the bonding surfaces of the semiconductor IC dies and/or the target substrates. In various embodiments, the bonding surfaces of the semiconductor IC dies and/or the target substrates may be inspected using the optical inspection system 112 after undergoing plasma pre-treatment using a treatment module 111 as described above to determine whether oxide material has been sufficiently removed from the bonding surface. In instances in which no oxide materials or only a negligible amount of oxide materials are detected, the semiconductor IC die and/or target substrate under inspection may be moved into the bonding chamber 106 to undergo an above-described bonding procedure. In instances in which a sufficient quantity of oxide materials is detected, the semiconductor IC die and/or target substrate under inspection may be subjected to another plasma treatment process to remove additional oxide materials. The semiconductor IC die and/or target substrate may then be reinspected by the optical inspection system 112 to determine whether the oxide material has been sufficiently removed. This process may be repeated until the oxide materials have been sufficiently removed, and the semiconductor IC die and/or target substrate under inspection may then be moved into the bonding chamber 106.

FIG. 1 illustrates one configuration of the semiconductor processing tool 100 that includes a single bonding chamber 106 and transfer module 110, a pair of holders 109 for the target substrates, three separate treatment modules 111, and three separate optical inspection systems 112. This may improve throughput by simultaneous inspection of semiconductor IC dies and/or target substrates. However, it will be understood that various alternative configurations for the semiconductor processing tool 100 may be utilized.

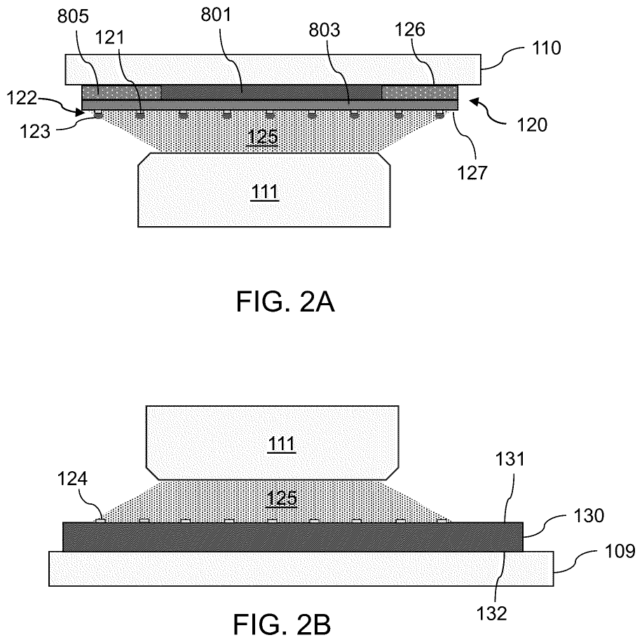

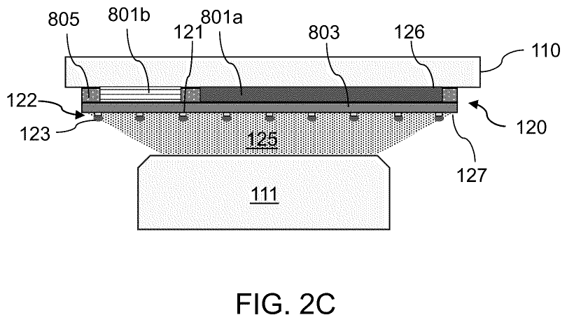

FIG. 2A is a vertical cross-sectional view illustrating a semiconductor IC die 120 undergoing a plasma treatment according to various embodiments of the present disclosure. Referring to FIG. 2A, the semiconductor IC die 120 may include any type of suitable semiconductor IC die, such as a logic die (e.g., a system-on-chip (SoC) die, an application specific integrated circuit (ASIC) die, a central processing unit die, a graphic processing unit die, etc.), a memory die (e.g., a high bandwidth memory (HBM) die, a dynamic random access memory (DRAM) die, etc.), an analog die, an RF die, an integrated passive device (IPD) die, a chiplet die, etc., including various combinations thereof. FIG. 2A illustrates an example semiconductor IC die 120 that includes a semiconductor “chip” 801 having device structures, an RDL structure 803 having conductive features therein that provide electrical interconnections for the chip 801 and a molding portion 805 surrounding the chip 801. Other suitable configurations for the semiconductor IC die 120 are within the scope of the disclosure. For example, FIG. 2C illustrates a multi-chip semiconductor IC die 120 that includes multiple chips 801, such as one or more logic chips 801a and one or more memory chips 801b disposed on an RDL structure 803, such as a semiconductor (e.g., silicon) or organic interposer, and surrounded by a molding portion 805. The semiconductor IC die 120 may be held by the transfer module 110 of the semiconductor processing tool 100, such as via the application of a vacuum suction force against a first (i.e., upper) surface 126 of the semiconductor IC die 120. A plurality of first bonding structures 122 may be located on the second (i.e., lower) surface 127 of the semiconductor IC die 120. In some embodiments, the first bonding structures 122 may include microbump bonding structures that include metal pillars 121 capped by a solder material portion 123. Suitable materials for the metal pillars 121 may include, for example, copper (Cu), palladium (Pd), rhodium (Rh), gold (Au), silver (Ag), nickel (Ni), aluminum (Al), tungsten (W), including alloys and combinations thereof. Suitable materials for the solder material portions 123 may include, for example, tin-silver (SnAg), tin-copper (SnCu), tin-gold-copper (SnAuCu), and tin-lead (SnPb). Other suitable materials for the metal pillars 121 and the solder material portions 123 are within the contemplated scope of disclosure.

FIG. 2A also illustrates an above-described treatment module 111 that is configured to direct a plasma jet 125 onto the second surface 127 of the semiconductor IC die 120. The treatment module 111 may be an APPJ module that may be configured to generate a relatively low-temperature plasma stream at atmospheric pressure. In an embodiment, a suitable process gas, such as an argon and hydrogen gas mixture, may be fed to the APPJ module 111. The gas may be ionized by the application of a high-voltage electrical discharge to produce a plasma. The plasma may be directed out from the APPJ module 111 via a nozzle to provide a plasma jet 125 that may be directed onto the second surface 127 of the semiconductor IC die 120. The plasma may react with oxide material on the surfaces of the first bonding structures 122, causing the oxide materials to break down into smaller molecules that may be removed from the surfaces of the first bonding structures 122. As discussed above, the presence of oxide materials on the bonding structures may result in poor bonding quality and can negatively affect the electrical conductivity of the bond. Thus, it may be desirable to remove oxide materials from the first bonding structures 122 prior to performing the bonding procedure. A plasma treatment using an APPJ module 111 may be an effective means for removing oxide material without damaging other components or materials of the semiconductor IC die 120.

In some embodiments, the plasma jet 125 emitted by the APPJ module 111 may be sufficiently large to cover all the first bonding structures 122 on the second surface 127 of the semiconductor IC die 120 simultaneously. Alternatively, the semiconductor IC die 120 may be moved relative to the APPJ module 111 such that the plasma jet 125 may scan over different regions of the first bonding structures 122. In the embodiment shown in FIGS. 1 and 2A, the APPJ module 111 may remain stationary while the transfer module 110 may move the semiconductor IC die 120 over the path of the plasma jet 125. Alternatively, the semiconductor IC die 120 may remain stationary and the APPJ module 111 may be moved, or both the semiconductor IC die and the APPJ module 111 may be moved relative to one another. Further, in the embodiment of FIGS. 1 and 2A, the APPJ module 111 emits the plasma jet 125 in a vertically upwards direction such that during the plasma pre-treatment process, the semiconductor IC die 120 is located above the APPJ module 111. In other embodiments, the APPJ module 111 may emit the plasma jet 125 along a different direction, such as a vertically downward or lateral direction, and the orientation of the semiconductor IC die 120 may be suitably modified such that the second surface 127 of the semiconductor IC die 120 is within the path of the plasma jet 125.

Additionally, in some embodiments, the effectiveness of the plasma pre-treatment may be enhanced by performing the plasma pre-treatment process in a low-oxygen environment.

FIG. 2B is a vertical cross-sectional view illustrating a substrate 130 undergoing a plasma treatment according to various embodiments of the present disclosure. Referring to FIG. 2B, the substrate 130 may be configured to provide mechanical support and electrical interconnections for a semiconductor IC die 120 to be subsequently bonded to the substrate 130. The substrate 130 may include a suitable substrate material, such as a semiconductor, glass, ceramic, and/or organic material. In some embodiments, the substrate 130 may be a semiconductor wafer, or may be a portion of a semiconductor wafer that has been separatee (e.g., diced) from the wafer to provide a semiconductor die. The semiconductor wafer or die may optionally include device structures (e.g., transistors, diodes, resistors, capacitors, etc.) formed on, over and/or within the semiconductor wafer or die.

The substrate 130 may include a first (i.e., upper) surface 131 and a second (i.e., lower) surface 132. A plurality of second bonding structures 124 may be located on the first (i.e., upper) surface 131 of the semiconductor IC die 120. In some embodiments, the second bonding structures 124 may include bonding pads composed of a suitable electrically-conductive material. Suitable materials for the bonding pads may include, for example, copper (Cu), palladium (Pd), rhodium (Rh), gold (Au), silver (Ag), nickel (Ni), aluminum (Al), tungsten (W), including alloys and combinations thereof. Other suitable materials for the bonding pads are within the contemplated scope of disclosure. The layout of the second bonding structures 124 may correspond to the layout of the first bonding structures 122 on the second (i.e., lower) surface 127 of the semiconductor IC die 120. The substrate 130 may be disposed an above-described holder 109 (e.g., a chuck) of the semiconductor processing tool 100, with the second (i.e., lower) surface 132 of the substrate 130 facing downwards towards the holder 109 and the first (i.e., upper) surface 131 of the substrate 130 facing upwards away from the holder 109.

FIG. 2B also illustrates an above-described treatment module 111, such as an APPJ module, that is configured to direct a plasma jet 125 onto first surface 131 of the substrate 130. The treatment module 111 may be equivalent to the treatment module 111 described above with reference to FIG. 2A. Thus, repeated discussion of like elements is omitted for brevity. The treatment module 111 (e.g., APPJ) may direct a plasma jet 125 over the first surface 131 of the substrate 130 to remove oxide material from the second bonding structures 124. In some embodiments, the plasma jet 125 may be scanned over the first surface 131 of the substrate 130 to ensure that all of the second bonding structures 124 are treated with plasma. In the embodiment shown in FIGS. 1 and 2B, the holder 109 and substrate 130 disposed thereon may remain stationary while the treatment module 111 may be moved over the first surface 131 of the substrate 130. Alternatively, the treatment module 111 may remain stationary and the holder 109 and substrate 130 may be moved, or both the holder 109/substrate 130 and the treatment module 111 may be moved relative to one another. Further, in the embodiment of FIGS. 1 and 2B, the treatment module 111 is located above the holder 109 and the substrate 130 and emits the plasma jet 125 in a vertically downwards direction towards the first surface 131 of the substrate 130. In other embodiments, the treatment module 111 may emit the plasma jet 125 along a different direction, such as a vertically upward or lateral direction, and the orientation of the holder 109 and the substrate 130 may be suitably modified such that the first surface 131 of the substrate 130 is within the path of the plasma jet 125. As in the case of the plasma treatment of the semiconductor IC die 120, the plasma treatment of the substrate 130 may also be performed in a low-oxygen environment.

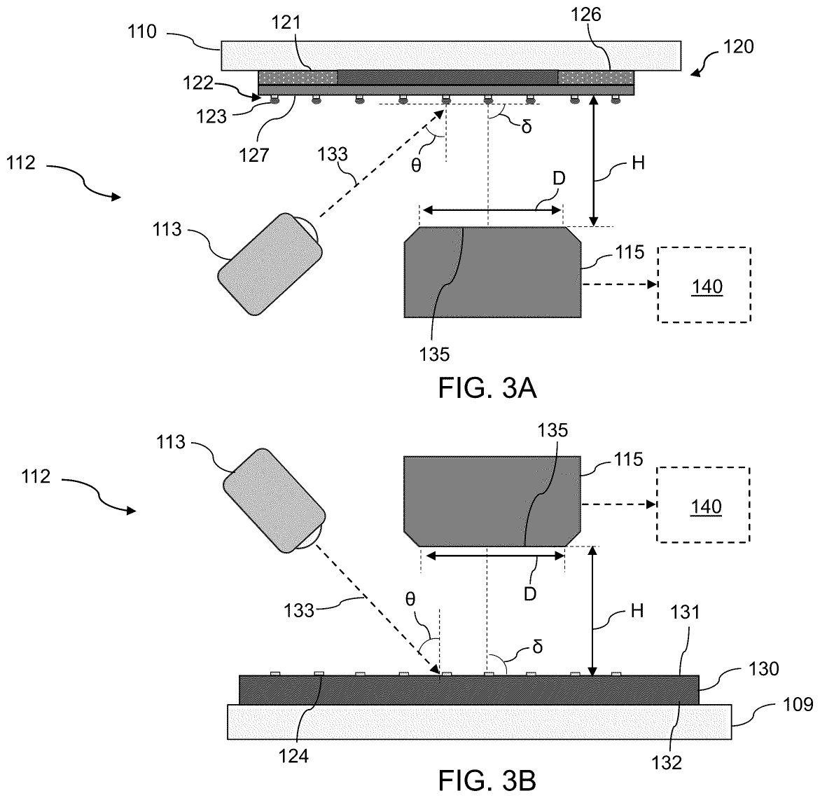

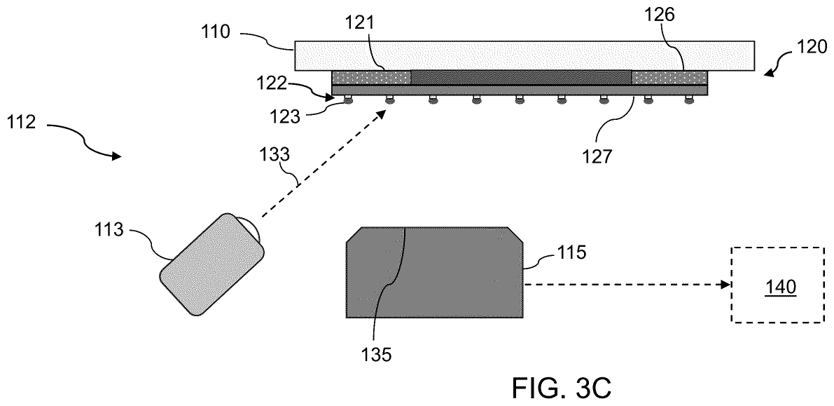

FIG. 3A is a vertical cross-sectional view illustrating an optical detection system 112 performing an inspection process on a semiconductor IC die 120 according to various embodiments of the present disclosure. The inspection process performed by the optical detection system 112 may be performed following the plasma pretreatment process as described above with reference to FIG. 2A. Referring to FIG. 3A, the optical inspection system 112 includes a light source 113 that directs light (schematically illustrated by arrow 133) onto the second (i.e., lower) surface 127 of the semiconductor IC die 120 and a camera 115 that obtains images of the second surface 127 of the semiconductor IC die 120 while it is illuminated by the light source 113. In various embodiments, the light source 113 may emit light within a particular wavelength range, such as light having a wavelength between about 10 nm and about 400 nm. In some embodiments, the wavelength of the light emitted by the light source 113 may be between about 365 nm and about 395 nm, which may help to provide effective contrast between first bonding structures 122 that have been fully de-oxidized and first bonding structures 122 that include residual oxide material. In some embodiments, the light source 113 may be an LED light source. In some embodiments, the light source 113 may be a ring light source, such as a low angle ring light source. Other suitable light sources 113 may also be utilized. Although a single light source 113 is shown in FIG. 3A, in some embodiments, more than one light source 113 may be used to illuminate the second surface 127 of the semiconductor IC die 120, which may increase throughput of the inspection process.

In various embodiments, the light 133 may be emitted at a particular incident angle with respect to the semiconductor IC die 120. Referring to FIG. 3A, the incident angle, θ, of the light 133 from the light source 113 may be defined as the angle between the light incident on the second surface of 127 of the semiconductor IC die 120 and a line normal to the planar surface of the semiconductor IC die 120 on which the first bonding structures 122 are formed. In various embodiments, the incident angle, θ, of the light 133 may be between about 20° and about 70°, such as between about 30° and about 50°, which may help to provide effective contrast between first bonding structures 122 that have been fully de-oxidized and first bonding structures 122 that include residual oxide material in the images obtained by the camera.

The camera 115 may be sensitive to light within the wavelength range of the light source 113, such as light in a wavelength range of 10-400 nm. The camera 115 may have a sensor area 135 having length and width dimensions, D, of at least about 0.01 cm. In some embodiments, the camera 115 may be a digital camera that includes at least about 5 megapixels. In some embodiments, the camera 115 may have a pixel size of at least about 3.5 μm. However, it will be understood that cameras having various characteristics may be utilized in accordance with various embodiments. During the optical inspection process, the sensor area 135 of the camera 115 may be located a distance, H, from the semiconductor IC die 120 that is between about 0.1 cm and about 30 cm. The camera 115 may have an orientation with respect to the semiconductor IC die 120 such that an angle, δ, may be defined between a line normal to the surface of the sensor area 135 and the planar lower surface of the semiconductor IC die 120 on which the first bonding structures 122 are formed. In various embodiments, the angle, δ, may be between about 60° and about 120°, such as between about 70° and about 110° (e.g., ˜90°). Although a single camera 115 is shown in FIG. 3A, in some embodiments, more than one camera 115 may be used to obtain images of the second surface 127 of the semiconductor IC die 120 during the optical inspection process.

In some embodiments, during the optical inspection process, the light source 113 may illuminate the entire second surface 127 of the semiconductor IC die 120 while the camera 115 may obtain an image of the entire second surface 127 of the semiconductor IC die 120, including all of the first bonding structures 122. Alternatively, the light source 113 and/or the camera 115 may be scanned across different regions of the semiconductor IC die 120 to obtain multiple images of the second surface 127 of the semiconductor IC die 120. This may include moving the semiconductor IC die 120 with respect to the light source 113 and camera 115, moving the light source 113 and camera 115 with respect to the semiconductor IC die 120, or both. FIG. 3C illustrates the light source 113 and the camera 155 moved with respect to the semiconductor IC die 120 as compared with FIG. 3A to image different regions of the second surface 127 of the semiconductor IC die 120. Further, in the embodiment of FIG. 3A, the semiconductor IC die 120 is held by the transfer module 110 above the light source 113 and camera 115. In other embodiments, the relative orientations of the light source 113 and camera 115 with respect to the second surface 127 of the semiconductor IC die 120 may be different. For example, the light source 113 and camera 115 may be located above the surface of the second surface 127 of the semiconductor IC die 120 (i.e., in a configuration as shown in FIG. 3B, below). In various embodiments, the optical inspection process of the semiconductor IC die 120 may be performed in a low-oxygen environment (e.g., an environment containing 0-20 vol. % oxygen).

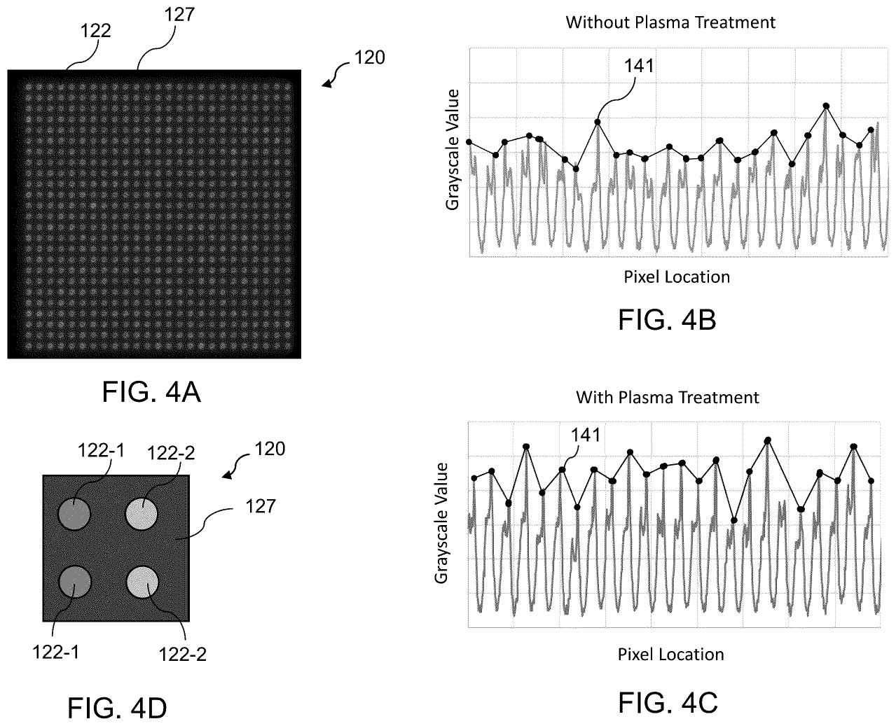

In some embodiments, the optical detection system 112 may additionally include a control system 140 (e.g., a computer) coupled to the camera 115, as schematically illustrated in FIG. 3A. In various embodiments, the control system 140 may be configured to receive images of the second surface 127 of the semiconductor IC die 120 obtained by the camera 115, and to analyze the images to detect for the presence of oxide material on the first bonding structures 122 of the semiconductor IC die 120. In various embodiments, characteristics of the images obtained by the camera 115 may indicate the presence or absence of oxide materials on the first bonding structures 122. In particular, it has been found that images of first bonding structures 122 having oxide materials over on their surfaces obtained while being illuminated by light from the light source 113 may be characterized by different grayscale values as compared to equivalent images of first bonding structures 122 that do not include oxide materials on their surfaces. FIG. 4A is a grayscale image of the second surface 127 of a semiconductor IC die 120 having an array of first bonding structures 122 that was obtained using a light source 113 and camera 115 as described above with reference to FIG. 3A. FIGS. 4B and 4C are plots illustrating the grayscale values for different pixel coordinates of an image of a semiconductor IC die 120 as shown in FIG. 4. Each of the peaks 141 in the plots of FIGS. 4B and 4C represents a different first bonding structure 122 on the semiconductor IC die 120. FIG. 4B is a plot showing the grayscale values for a semiconductor IC die 120 that was not subjected to a plasma pre-treatment to remove oxide materials as described above with reference to FIG. 2A. FIG. 4C is a plot showing the grayscale values for a semiconductor IC die 120 after undergoing a plasma pre-treatment to remove oxide materials. As may be seen from a comparison of FIGS. 4B and 4C, the grayscale values for the first bonding structures 122 are lower in the plot of FIG. 4B (no plasma treatment) compared with those in the plot of FIG. 4C (with plasma treatment). Thus, the untreated first bonding structures 122 containing oxide materials may have lower grayscale values than the plasma-treated first bonding structures 122 having less or no oxide materials remaining. This is schematically illustrated in FIG. 4D, which is an enlarged view of a portion of a grayscale image of the second surface 127 of a semiconductor IC die 120. As shown in FIG. 4D, the first bonding structures 122-1 having a greater quantity of oxide materials remaining on the first bonding structures 122-1 have a comparatively darker color (i.e., a lower grayscale value) than the first bonding structures 122-2 having a lesser quantity of oxide materials remaining on the first bonding structures 122-2, which have a comparatively lighter color (i.e., a higher grayscale value).

In some embodiments, the control system 140 of the optical inspection system 112 may be configured to perform an image binarization process on the images received from the camera 115. Image binarization is a technique that may be used to create a binary image from a grayscale or color image. In various embodiments, an algorithm may be utilized to compare the grayscale values of each pixel of an image to a pre-determined threshold value. In instances in which the pixel value is less than the threshold value, the pixel value may be set to zero in the binary image. In instances in which the pixel value is equal to or greater than the threshold value, the pixel value may be set to the maximum value (e.g., 255) in the binary image. For detecting the presence of oxide materials on the first bonding structures 122 of a semiconductor IC die 120, the threshold value may be set to correspond to a value indicating that oxide materials have been sufficiently removed from the first bonding structures 122. Thus, in instances in which a sufficient amount of oxide materials have been removed from all of the first bonding structures 122, each of the first bonding structures 122 may be visible in the binary image, since images of the first bonding structures 122 having no or negligible oxide materials will have grayscale values at or above the threshold value. In contrast, where the oxides have not been sufficiently removed, some or all of the first bonding structures 122 will not be visible in the binary image, as images of first bonding structures 122 having a significant quantity of oxide materials will have grayscale values below the threshold value.

In embodiments in which the control system 140 of the optical inspection system 112 determines that no oxide materials or only a negligible amount of oxide materials are present on the first bonding structures 122, the semiconductor IC die 120 may be moved into the bonding chamber 106 of the semiconductor processing tool 100 to undergo a bonding procedure as described in further detail below. In embodiments in which the control system 140 of the optical inspection system 112 determines that an unacceptable amount of oxide materials is present on one or more of the first bonding structures 122, the semiconductor IC die 120 may be subjected to an additional plasma treatment process to remove additional oxide materials. Following the additional plasma treatment, the semiconductor IC die 120 may then undergo another inspection by the optical inspection system 112 to determine whether the oxide material has been sufficiently removed. This process may be repeated until enough of the oxide materials have been removed, and the semiconductor IC die 120 may then be moved into the bonding chamber 106.

FIG. 3B is a vertical cross-sectional view illustrating an optical detection system 112 performing an inspection process on a substrate 130 according to various embodiments of the present disclosure. The optical inspection process performed by the optical detection system 112 may be performed following the plasma pretreatment process as described above with reference to FIG. 2B. The optical detection system 112 and the inspection process shown in FIG. 3B may be similar to the optical detection system 112 inspection process described above with reference to FIG. 3A. Thus, repeated discussion of like elements is omitted for brevity. In the inspection process shown in FIG. 3B, the light source 113 may direct light within a particular wavelength range (e.g., light having a wavelength between 10 nm and 400 nm) onto the first (i.e., upper) surface 131 of the substrate 130 and the camera 115 may obtain an image of the first surface 131 of the substrate 130 while it is illuminated by the light source 113. The control system 140 may receive the images of the first surface 131 of the substrate 130 obtained by the camera 115 and may analyze the images to detect for the presence of oxide material on the second bonding structures 124, as was described above with reference to FIG. 3A.

In some embodiments, during the inspection process, the light source 113 may illuminate the entire first surface 131 of the substrate 130 while the camera 115 may obtain an image of the entire first surface 131 of the substrate 130, including all of the second bonding structures 124. Alternatively, the light source 113 and/or the camera 115 may be scanned across different regions of the substrate 130 to obtain multiple images of the first surface 131 of the substrate 130. This may include moving the substrate 130 with respect to the light source 113 and camera 115, moving the light source 113 and camera 115 with respect to the substrate 130, or both. Further, in the embodiment of FIG. 3B, the light source 113 and camera 115 are located above the substrate 130. In other embodiments, the relative orientations of the light source 113 and camera 115 with respect to the first surface 131 of the substrate 130 may be different. For example, the light source 113 and camera 115 may be located below or to the surface of the first surface 131 of the 130. In various embodiments, the optical inspection process of the substrate 130 may be performed in a low-oxygen environment.

In embodiments in which the control system 140 of the optical inspection system 112 determines that no oxide materials or only a negligible amount of oxide materials are present on the second bonding structures 124, the substrate 130 may be moved into the bonding chamber 106 of the semiconductor processing tool 100 to undergo a bonding procedure as described in further detail below. In embodiments in which the control system 140 of the optical inspection system 112 determines that an unacceptable amount of oxide materials is present on one or more of the second bonding structures 124, the substrate 130 may be subjected to an additional plasma treatment process to remove additional oxide materials. Following the additional plasma treatment, the substrate 130 may then undergo another inspection by the optical inspection system 112 to determine whether the oxide material has been sufficiently removed. This process may be repeated until enough of the oxide materials have been removed, and the substrate 130 may then be moved into the bonding chamber 106.

Thus, in various embodiments, one or more optical inspection systems 112 may be utilized to ensure that oxide materials have been sufficiently removed from the first bonding structures 122 and the second bonding structures 124 of the semiconductor IC dies 120 and the substrates 130 before they are provided to the bond chamber 106 for bonding. This may lead to improved bond quality, increased yields, a larger process window and better reliability of the bonded device structures 150.

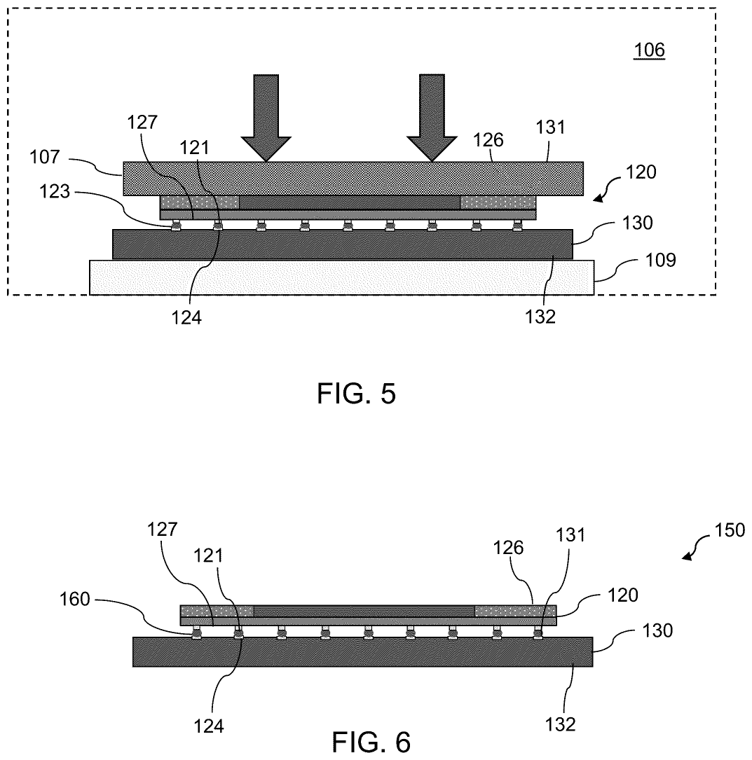

FIG. 5 is a vertical cross-section view of a bonding process used to bond a semiconductor IC die 120 to a substrate 130 according to various embodiments of the present disclosure. Referring to FIG. 5, following the inspection process described above with reference to FIGS. 3A and 3B, a substrate 130 and a semiconductor IC die 120 may be moved into a bonding chamber 106 of a semiconductor processing tool 100. The semiconductor IC die 120 may be transferred from the transfer module 110 to a bond head 107 of the bonding chamber 106 such that the semiconductor IC die 120 may be temporarily adhered to a lower surface of the bond head 107. In some embodiments, the semiconductor IC die 120 may be adhered to the lower surface of the bond head 107 via application of a vacuum suction force. The substrate 130 may be disposed on a suitable support surface within the bonding chamber 106. The substrate 130 and the semiconductor IC die 120 may be oriented such that the first (i.e., upper) surface 131 of the substrate 130 may face towards the second (i.e., lower) surface 127 of the semiconductor IC die 120. An actuator system (not shown in FIG. 5) may be configured to move the bond head 107 and the semiconductor IC die 120 to align the semiconductor IC die 120 over the surface of a substrate 130 such that each of the first bonding structures 122 on the second surface 127 of the semiconductor IC die 120 may be aligned over corresponding second bonding structures 124 on the first surface 131 of the substrate 130. An optical camera 108 as described above with reference to FIG. 1 may be used to ensure that the first bonding structures 122 on the semiconductor IC die 120 are properly aligned with the second bonding structures 124 on the substrate 130. The actuator system may then move the semiconductor IC die 120 in a vertically downward direction such that the first bonding structures 122 on the semiconductor IC die 120 may contact corresponding second bonding structures 124 on the substrate 130.

A bonding process, such as a thermocompression bonding process, may then be performed to bond the first bonding structures 122 on the semiconductor IC die 120 to the second bonding structures 124 on the substrate 130. The bonding process may include applying heat and pressure to the semiconductor IC die 120 and the substrate 130 to cause the solder material portions 123 located between the metal pillars 121 of the first bonding structures 122 and the second bonding structures 124 to undergo a reflow process. In some embodiments, the bond head 107 may be used to apply a compressive force to the semiconductor IC die 120 and the substrate 130 during the bonding process. The compressive force applied by the bond head 107 during the bonding process may be between about 500 g and about 30 kg. During the bonding process, the temperature in the bonding chamber 106 may be between about 25° C. and about 400° C. In various embodiments, the bonding process may be performed in a low oxygen environment. In some embodiments, nitrogen gas may fill the bond chamber 106 during the bonding process. In various embodiments, the bonding process may be a fluxless bonding process that is performed without the use of a flux material. Following the bonding process, the semiconductor IC die 120 may be released by the bond head 107.

FIG. 6 is a vertical cross-section view of a bonded device structure 150 according to various embodiments of the present disclosure. Referring to FIG. 6, following the bonding process described above, the solder material portions 123 between the metal pillars 121 of the first bonding structures 122 and the second bonding structures 124 may cool and resolidify to form a plurality of bond joints 160 that mechanically and electrically couple the semiconductor IC die 120 to the substrate 130 to provide a bonded device structure 150. As discussed above, the above-described plasma pretreatment and optical inspection processes may help to ensure that oxide materials may be sufficiently removed from the first bonding structures 122 and the second bonding structures 124 prior to performing the bonding process. This may lead to improved bond quality, increased yields, a larger process window and better reliability of the bonded device structures 150.

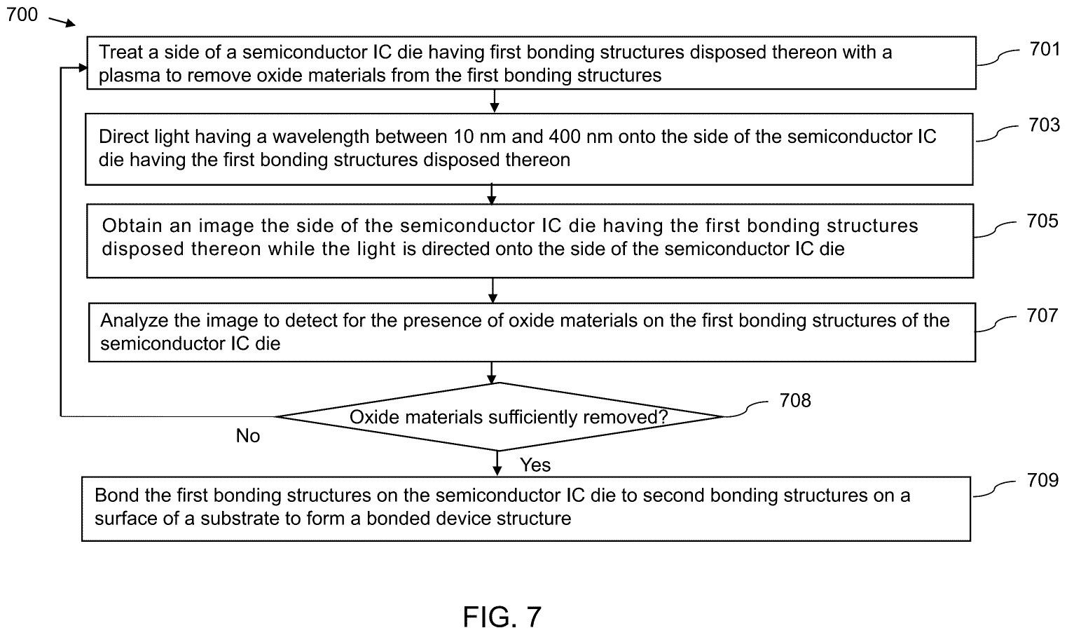

FIG. 7 is a flowchart illustrating a method 700 of fabricating a bonded device structure 150 according to various embodiments of the present disclosure. Referring to FIGS. 1, 2A and 7, in step 701 of method 700, a second surface 127 of a semiconductor IC die 120 having first bonding structures 122 disposed thereon may be treated with a plasma to remove oxide materials from the first bonding structures 122. Referring to FIGS. 1, 3A and 7, in step 703 of method 700, light having a wavelength between 10 nm and 400 nm may be directed onto the second surface 127 of the semiconductor IC die 120 having the first bonding structures 122 disposed thereon. Referring to FIGS. 1, 3A and 7, in step 705 of method 700, an image of the second surface 127 of the semiconductor IC die 120 having the first bonding structures 122 disposed thereon may be obtained while the light is directed onto the second surface 127 of the semiconductor IC die 120. Referring to FIGS. 1, 3A, 4C and 7, in step 707 of method 700, the image may be analyzed to detect for the presence of oxide materials on the first bonding structures 122 of the semiconductor IC die 120. Referring to FIGS. 1, 2A, 3A and 5-7, in determination block 708, a determination may be made as to whether or not oxide materials have been sufficiently removed from the first bonding structures 122 based on the analysis of the image in step 707. In response to a determination that the oxide materials have not been sufficiently removed (i.e., determination block 708=“No”) the method 700 may repeat steps 701 through 707 to perform additional plasma treatment and optical inspection. In response to a determination that the oxide materials have been sufficiently removed (i.e., determination block 708=“Yes”), the first bonding structures 122 on the semiconductor IC die 120 may be bonded to second bonding structures 124 located on a surface 131 of a substrate 130 to form a bonded device structure 150 in block 709 of method 700.

Referring to all drawings and according to various embodiments of the present disclosure, a semiconductor processing tool 100 includes a treatment module 111 configured to treat surfaces 127, 131 of device structures 120, 130 with a plasma to remove oxide materials from bonding structures 122, 124 located on the surfaces 127, 131 of the device structures 120, 130, an optical inspection system 112 configured to direct light in a wavelength range of 10 nm to 400 nm onto the surfaces 127, 131 of the device structures 120, 130, obtain images of the light reflected from the surfaces 127, 131 of the device structures 120, 130, and analyze the images to detect for the presence of oxide materials on the bonding structures 122, 124 located on the surfaces 127, 131 of the device structures 120, 130, and a bond chamber 106 including a bond head 107 configured to bond first bonding structures 122 located on a surface 127 of a first device structure 120 to second bonding structures 124 located on a surface 131 of a second device structure 130 to form a bonded device structure 150.

In one embodiment, the light directed onto the surfaces of the devices structures is in a wavelength range of 365 nm to 395 nm. In another embodiment, an angle θ between the light incident on the surfaces of the device structures 120, 130 and a line that is normal to the surfaces of the device structures 120, 130 is between 20° and 70°. In another embodiment, the angle θ between the light incident on the surfaces of the device structures 120, 130 and the line that is normal to the surfaces of the device structures is between 30° and 50°. In another embodiment, the semiconductor processing tool 100 is configured to move device structures 120, 121 into the bond chamber 106 in response to a determination by the optical inspection system 112 that oxide materials have been sufficiently removed from the bonding structures 122, 124 located on the second surface 127, 131 of the device structures 120, 130, and perform an additional plasma treatment on the second surface 127, 131 of the device structures 120, 130 including the bonding structures 122, 124 using the treatment module 111 in response to a determination by the optical inspection system 112 that oxide materials have not been sufficiently removed from the bonding structures 122, 124 located on the surfaces 127, 131 of the device structures 120, 130.

In another embodiment, the optical inspection system 112 analyzes the images to detect for the presence of oxide materials by comparing grayscale values of pixels in the images to a threshold value. In another embodiment, the optical inspection system 112 analyzes the images to detect for the presence of oxide materials by performing an image binarization process. In another embodiment, the first device structure 120 comprises a semiconductor integrated circuit (IC) die 120 having first bonding structures 122 including metal pillars 121 capped by solder material portions 123 on a lower surface 127 of the semiconductor IC die 120, and the second device structure 130 includes a semiconductor wafer, a semiconductor IC die, and/or a substrate having second bonding structures 124 on an upper surface 131 of the second device structure 130. In another embodiment, the bond head 107 is configured to secure a semiconductor IC die 120 to a lower surface of the bond head 107, align the semiconductor IC die 120 over a second device structure 130 located in the bond chamber 106 such that each of the first bonding structures 122 on the lower surface 127 of the semiconductor IC die 120 is aligned over a corresponding second bonding structure 124 on the upper surface 131 of the second device structure 130, move the semiconductor IC die 120 towards the second device structure 130 such that the first bonding structures 122 contact the second bonding structures 122, and apply a compressive force to the semiconductor IC die 120 and the second device structure 130 during the bonding process.

In another embodiment, the compressive force applied by the bond head 107 during the bonding process between 500 g and about 30 kg, a temperature in the bond chamber 106 is between 25° C. and 400° C. during the bonding process, and the bonding is performed without the presence of a flux material. In another embodiment, the treatment module 111 includes an atmospheric pressure plasma jet module.

Another embodiment is drawn to an optical inspection system 112 for a semiconductor IC die 120 including a light source 113 configured to direct light in a wavelength range of 10 nm to 400 nm onto a surface 127 of the semiconductor IC die 120 having a plurality of bonding structures 122 disposed thereon, a camera 115 sensitive to light in the wavelength range of 10 nm to 400 nm and configured to obtain images of the surface of the semiconductor IC die having a plurality of first bonding structures disposed thereon while the light source 113 directs the light onto the surface 127 of the semiconductor IC die 120, and a control system 140 configured to receive the image of the surface 127 of the semiconductor IC die 120 obtained by the camera 115 and to analyze the image to detect for the presence of oxide materials on the bonding structures 122 of the semiconductor IC die 120.

In one embodiment, the camera 115 includes a sensor area 135 having dimensions D of at least 0.01 cm×0.01 cm and a distance H between the sensor area 135 of the camera 115 and the semiconductor IC die 120 is between 0.1 cm and 30 cm.

In another embodiment, a first angle θ between the light incident on the surface 127 of the semiconductor IC die 120 and a line that is normal to a planar surface of the semiconductor IC die 120 on which the bonding structures 122 are located is between 20° and 70°, and a second angle δ between a line normal to the sensor area 135 of the camera 115 and the planar surface of the semiconductor IC die 120 is between 60° and 120°.

In another embodiment, the first angle θ is between 30° and 50°, and the second angle δ is between 70° and 110°.

In another embodiment, the image obtained by the camera 115 is a grayscale image, and the control system 140 detects for the presence of oxide materials on the bonding structures 122 based on an evaluation of grayscale values of pixels of the image corresponding to the locations of the bonding structures 122.

Another embodiment is drawn to a method of forming a bonded device structure 150 that includes treating a surface 127 of a semiconductor integrated circuit (IC) die 120 having first bonding structures 122 disposed thereon with a plasma to remove oxide materials from the first bonding structures 122, directing light having a wavelength between 10 nm and 400 nm onto the surface 127 of the semiconductor IC die 120 having the first bonding structures 122 disposed thereon, obtaining an image of the surface 127 of the semiconductor IC die 120 having the first bonding structures 122 disposed thereon while the light is directed onto the surface 127 of the semiconductor IC die 120, analyzing the image to detect for the presence of oxide materials on the first bonding structures 122 of the semiconductor IC die 120, bonding the first bonding structures 122 on the semiconductor IC die 120 to second bonding structures 124 located on a surface 131 of a substrate 130 to form a bonded device structure 150.

In one embodiment, the method further includes treating the surface 131 of the substrate 130 on which the second bonding structures 124 are located with a plasma, directing light having a wavelength between 10 nm and 400 nm onto the surface 131 of the substrate 130 on which the second bonding structures 124 are located, obtaining an image of the surface 131 of the substrate 130 on which the second bonding structures 124 are located while the light is directed onto the surface 131 of the substrate 130, and analyzing the image to detect for the presence of oxide materials on the second bonding structures 124 of the substrate 130 prior to bonding the first bonding structures 122 on the semiconductor IC die 130 to the second bonding structures 124 on the substrate 130 to form the bonded device structure 130.

In another embodiment, the method further includes, in response to detecting the presence of oxide materials on the first bonding structures 122 of the semiconductor IC die 130, performing one or more additional plasma treatments and obtaining and analyzing at least one additional image of the surface 127 of the semiconductor IC die 120 including the first bonding structures 122 prior to bonding the first bonding structures 122 on the semiconductor IC die 120 to the second bonding structures 124 on the substrate 130 to form the bonded device structure 130.

In another embodiment, the first bonding structures 122 on the semiconductor IC die 130 are bonded to the second bonding structures 124 on the substrate 130 using a fluxless thermocompression bonding process.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A semiconductor processing tool, comprising:
a treatment module configured to treat surfaces of device structures with a plasma to remove oxide materials from bonding structures located on the surfaces of the device structures;
an optical inspection system configured to:
direct light in a wavelength range of 10 nm to 400 nm onto the surfaces of the device structures;
obtain images of the surfaces of the device structures while the light is directed onto the surfaces of the device structures; and
analyze the images of the surfaces of the device structures to detect the presence of oxide materials on the bonding structures located on the surfaces of the device structures; and
a bond chamber comprising a bond head configured to bond first bonding structures located on a surface of a first device structure to second bonding structures located on a surface of a second device structure to form a bonded device structure.

2. The semiconductor processing tool of claim 1, wherein the light directed onto the surfaces of the devices structures is in a wavelength range of 365 nm to 395 nm.

3. The semiconductor processing tool of claim 1, wherein an angle between the light incident on the surfaces of the device structures and a line that is normal to the surfaces of the device structures is between 20° and 70°.

4. The semiconductor processing tool of claim 3, wherein the angle between the light incident on the surfaces of the device structures and the line that is normal to the surfaces of the device structures is between 30° and 50°.

5. The semiconductor processing tool of claim 1, wherein the semiconductor processing tool is configured to:
move device structures into the bond chamber in response to a determination by the optical inspection system that oxide materials have been sufficiently removed from the bonding structures located on the surfaces of the device structures; and
perform an additional plasma treatment on the surfaces of device structures including the bonding structures using the treatment module in response to a determination by the optical inspection system that oxide materials have not been sufficiently removed from the bonding structures located on the surfaces of the device structures.

6. The semiconductor processing tool of claim 1, wherein the optical inspection system analyzes the images to detect for the presence of oxide materials by comparing grayscale values of pixels in the images to a threshold value.

7. The semiconductor processing tool of claim 1, wherein the optical inspection system analyzes the images to detect for the presence of oxide materials by performing an image binarization process.

8. The semiconductor processing tool of claim 1, wherein the first device structure comprises a semiconductor integrated circuit (IC) die having first bonding structures comprising metal pillars capped by solder material portions on a lower surface of the semiconductor IC die, and the second device structure comprises a semiconductor wafer, a semiconductor IC die, and/or a substrate having second bonding structures on an upper surface of the second device structure.

9. The semiconductor processing tool of claim 8, wherein the bond head is configured to secure a semiconductor IC die to a lower surface of the bond head, align the semiconductor IC die over a second device structure located in the bond chamber such that each of the first bonding structures on the lower surface of the semiconductor IC die is aligned over a corresponding second bonding structure on the upper surface of the second device structure, move the semiconductor IC die towards the second device structure such that the first bonding structures contact the second bonding structures, and apply a compressive force to the semiconductor IC die and the second device structure to bond the first bonding structures to the second bonding structures.

10. The semiconductor processing tool of claim 9, wherein the compressive force applied by the bond head during the bonding process between 500 g and about 30 kg, a temperature in the bond chamber is between 25° C. and 400° C. during the bonding process, and the bonding is performed without a presence of a flux material.

11. The semiconductor processing tool of claim 1, wherein the treatment module comprises an atmospheric pressure plasma jet module.

12. An optical inspection system for a semiconductor integrated circuit (IC) die, comprising:
a light source configured to direct light in a wavelength range of 10 nm to 400 nm onto a surface of the semiconductor IC die having a plurality of bonding structures disposed thereon;
a camera that is sensitive to light in the wavelength range of 10 nm to 400 nm and configured to obtain images of the surface of the semiconductor IC die having a plurality of bonding structures disposed thereon while the light source directs the light onto the surface of the semiconductor IC die; and
a control system configured to receive the image of the surface of the semiconductor IC die obtained by the camera and to analyze the image to detect for the presence of oxide materials on the bonding structures of the semiconductor IC die.

13. The optical inspection system of claim 12, wherein the camera comprises a sensor area having dimensions of at least 0.01 cm×0.01 cm and a distance between the sensor area of the camera and the semiconductor IC die is between 0.1 cm and 30 cm.

14. The optical inspection system of claim 13, wherein:
a first angle between the light incident on the surface of the semiconductor IC die and a line that is normal to a planar surface of the semiconductor IC die on which the bonding structures are located is between 20° and 70°, and
a second angle between a line normal to the sensor area of the camera and the planar surface of the semiconductor IC die is between 60° and 120°.

15. The optical inspection system of claim 14, wherein the first angle is between 30° and 50°, and the second angle is between 70° and 110°.

16. The optical inspection system of claim 12, wherein the image obtained by the camera comprises a grayscale image, and the control system detects for the presence of oxide materials on the bonding structures based on an evaluation of grayscale values of pixels of the images corresponding to the locations of the bonding structures.

17. A method of forming a bonded device structure, comprising:
treating a surface of a semiconductor integrated circuit (IC) die having first bonding structures disposed thereon with a plasma to remove oxide materials from the first bonding structures;
directing light having a wavelength between 10 nm and 400 nm onto the surface of the semiconductor IC die having the first bonding structures disposed thereon;
obtaining an image of the surface of the semiconductor IC die having the first bonding structures disposed thereon while the light is directed onto the surface of the semiconductor IC die;
analyzing the image to detect for the presence of oxide materials on the first bonding structures of the semiconductor IC die; and
bonding the first bonding structures on the semiconductor IC die to second bonding structures located on a surface of a substrate to form a bonded device structure.

18. The method of claim 17, further comprising:
treating the surface of the substrate on which the second bonding structures are located with a plasma;
directing light having a wavelength between 10 nm and 400 nm onto the surface of the substrate on which the second bonding structures are located;
obtaining an image of the surface of the substrate on which the second bonding structures are located while the light is directed onto the surface of the substrate; and
analyzing the image to detect for the presence of oxide materials on the second bonding structures of the substrate prior to bonding the first bonding structures on the semiconductor IC die to the second bonding structures on the substrate to form the bonded device structure.

19. The method of claim 17, further comprising:
in response to detecting the presence of oxide materials on the first bonding structures of the semiconductor IC die, performing one or more additional plasma treatments and obtaining and analyzing at least one additional image of the surface of the semiconductor IC die including the first bonding structures prior to bonding the first bonding structures on the semiconductor IC die to the second bonding structures on the substrate to form the bonded device structure.

20. The method of claim 17, wherein the first bonding structures on the semiconductor IC die are bonded to the second bonding structures on the substrate using a fluxless thermocompression bonding process.
